(19) United States
(12) Patent Application Publication
(10) Pub. No.: US 2023/0067444 A1
(43) Pub. Date: Mar. 2, 2023

(54) SOLAR CELL

(71) Applicant: United Renewable Energy Co., Ltd., Hsinchu City (TW)

(72) Inventors: Hung-Ming LIN, HSINCHU CITY (TW); Hsiu-Hung LIU, HSINCHU CITY (TW); Chen-Po YU, HSINCHU CITY (TW); Chun-Liang CHIANG, HSINCHU CITY (TW)

(73) Assignee: United Renewable Energy Co., Ltd., HSINCHU CITY (TW)

(21) Appl. No.: 17/517,255

(22) Filed: Nov. 2, 2021

(30) Foreign Application Priority Data
Aug. 26, 2021 (TW) 110131752

(51) Int. Cl. H01L 31/0216; H01L 31/0224; H01L 31/0236; H01L 31/048

(52) U.S. Cl. CPC H01L 31/02167; H01L 31/022425; H01L 31/02168; H01L 31/02363; H01L 31/0488

(57) ABSTRACT

A solar cell includes a silicon substrate, a passivation layer, a first protection layer, a second protection layer, and a third protection layer. The material of the passivation layer is aluminum oxide, and the passivation layer is on the lower surface of the silicon substrate. The material of the first protection layer is silicon oxynitride, and the first protection layer is on a surface of the passivation layer opposite to the silicon substrate. The material of the second protection layer is silicon nitride, and the second protection layer is on a surface of the first protection layer opposite to the passivation layer. The material of the third protection layer is silicon oxynitride or silicon oxide, and the third protection layer is on a surface of the second protection layer opposite to the first protection layer.

### CROSS-REFERENCE TO RELATED APPLICATION

This non-provisional application claims priority under 35 U.S.C. § 119(a) to Patent Application No. 110131752 in Taiwan, R.O.C. on Aug. 26, 2021, the entire contents of which are hereby incorporated by reference.

### BACKGROUND

### Technical Field

The instant disclosure relates to a solar cell, in particular, to a surface deposition layer structure of a solar cell.

### Related Art

Please refer to FIG. 1 illustrates a schematic view showing that multiple solar cell modules are in series-parallel connection, and FIG. 1 shows the connection structure of these solar cells for power generation. To achieve proper electrical energy collection, one current configuration known to the inventors is to electrically connect multiple solar cell modules 901 in parallel with a convergence box 902 to form a solar power generation system 900, wherein the multiple solar cell modules 901 are in series connection. The main function of the convergence box 902 is to collectively control the currents generated by each of the solar cell modules 901. In addition, the convergence box 902 can collect and monitor power generation data of each of the solar cell modules 901. Besides, the convergence box 902 protects the whole solar power generation system 900 from getting lightning. Under such configuration, one of two terminals of the multiple solar cell modules 901 is a positive potential relative to the potential of the ground, and the other terminal is a negative potential relative to the potential of the ground.

### SUMMARY

However, the problem of the current configuration known to the inventor is that the negative potential terminal of the multiple solar cell modules 901 is prone to have the potential induced degradation (PID) effect. As a result, the PID effect not only causes damages of the solar cell module 901, but also reduces the power generation efficiency.

In view of this, a solar cell is provided. In one embodiment, the solar cell comprises a silicon substrate, an aluminum oxide layer, a first silicon oxynitride layer, a silicon nitride layer, and a second silicon oxynitride layer. The silicon substrate comprises a first doping material, and the silicon substrate has a lower surface. The aluminum oxide layer is on the lower surface of the silicon substrate. The first silicon oxynitride layer is on a surface of the aluminum oxide layer opposite to the silicon substrate. The silicon nitride layer is on a surface of the first silicon oxynitride layer opposite to the aluminum oxide layer. The second silicon oxynitride layer is on a surface of the silicon nitride layer opposite to the first silicon oxynitride layer.

Additionally, another solar cell is also provided. In one embodiment, the solar cell comprises a silicon substrate, an aluminum oxide layer, a silicon oxynitride layer, a silicon nitride layer, and a silicon oxide layer. The silicon substrate comprises a first doping material, and the silicon substrate has a lower surface. The aluminum oxide layer is on the lower surface of the silicon substrate. The silicon oxynitride layer is on a surface of the aluminum oxide layer opposite to the silicon substrate. The silicon nitride layer is on a surface of the silicon oxynitride layer opposite to the aluminum oxide layer. The silicon oxide layer is on a surface of the silicon nitride layer opposite to the silicon oxynitride layer.

### BRIEF DESCRIPTION OF THE DRAWINGS

The disclosure will become more fully understood from the detailed description given herein below for illustration only, and thus not limitative of the disclosure, wherein:

FIG. 1 illustrates a schematic view showing that multiple solar cell modules are in series-parallel connection;

FIG. 2 illustrates a schematic view showing layers of an upper surface of a monofacial solar cell; and

FIG. 3 illustrates a schematic view of a bifacial solar cell according to one embodiment of the instant disclosure.

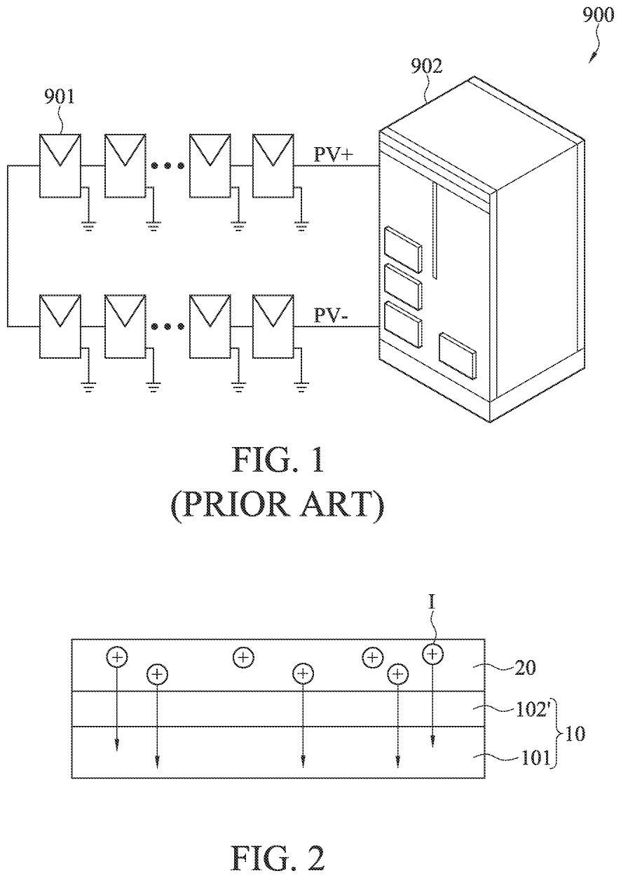

### DETAILED DESCRIPTION

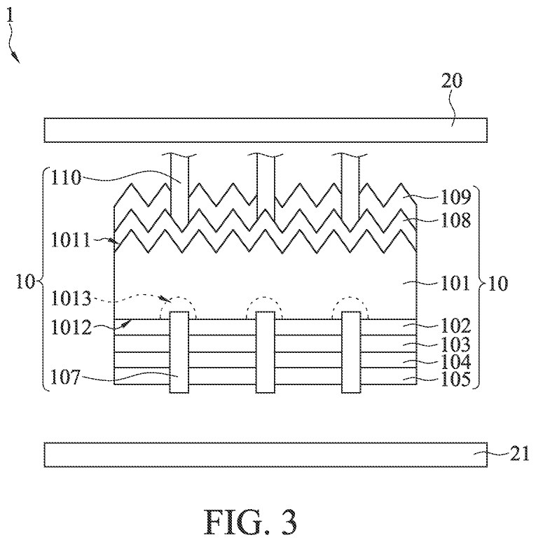

FIG. 2 illustrates a schematic view showing layers of an upper surface of a monofacial solar cell. FIG. 3 illustrates a schematic view of a bifacial solar cell according to one embodiment of the instant disclosure. As shown in FIG. 2 and FIG. 3, in this embodiment, the solar cell module 1 comprises a solar cell 10, an upper glass 20 covering the upper surface of the solar cell 10, and a lower glass 21 covering the lower surface of the solar cell 10. Besides, the upper surface of the solar cell 10 may be further attached and covered by an encapsulation film. The encapsulation film can protect the metal circuits on the upper surface of the solar cell 10 and also can avoid from forming a gap between the solar cell 10 and the upper glasses 20 to affect heat dissipation. Similarly, the lower surface of the solar cell 10 may be further attached and covered by an encapsulation film. The encapsulation film can protect electrodes and metal circuits (if any) on the lower surface of the solar cell 10, and can avoid from forming a gap between the solar cell 10 and the lower glasses 21 to affect heat dissipation. The material of the encapsulation film may be ethylene-vinyl acetate copolymer (Ethylene-Vinyl Acetate, EVA), Polyolefin Elastomers (POE), or the like.

Please refer to FIG. 2. A passivation layer 102′ is on the upper surface of the silicon substrate 101 of the solar cell 10. According to some embodiments, the passivation layer 102′ is a single-layered silicon nitride. The silicon substrate 101 comprises a first doping material. A heterogeneous doping layer (which is not shown in FIG. 2) comprising a second doping material is on the interface between the silicon substrate 101 and the passivation layer 102′. The second doping material is different from the first doping material. For example, the first doping material is boron, which makes the silicon substrate 101 as a p-type semiconductor. The second doping material is phosphor, which makes the silicon substrate 101 as an n-type semiconductor. When the solar cell 10 is illuminated by light, photons with energy larger than a band gap can excite the electrons in the depletion region of the p-n junction of the solar cell 10 to transit from valence band to the conduction band, and then the electrons are collected by the electrodes and transmit to outside. The upper glass 20 on the upper surface of the solar cell 10 comprise metal ions I, such as sodium ions. When the silicon substrate 101 is at a negative potential, the positively charged metal ions I are driven by the negative potential to the silicon substrate 101 and to neutralize the potential of the p-n junction. Therefore, the power generation efficiency of the solar cell 10 is reduced. This phenomenon is called the shunting type PID (PID-shunting, or PID-s). The silicon nitride of the passivation layer 102′ contains a high density of fixed positive charges, and the fixed positive charges in high density cause a certain electrical repulsion against the metal ions I so to reduce the accumulation of the metal ions I.

According to the types of the solar cell 10 adopted in the solar cell module 1, some solar cell modules 1 may comprise only the upper glass 20 but is devoid of the lower glass 21. The solar cell module 1 with such single-sided glass module structure generally adopts monofacial solar cells for power generation. This also indicates that for such configuration, only the upper surface of the solar cell 10 is illuminated by light, and the lower surface of the solar cell 10 is completely covered with a metal layer (such as an aluminum layer) to form a back-contact solar cell. Thus, for such configuration, the PID effect mainly occurs on the upper surface of the solar cell 10. It should be noted that, according to the instant disclosure, the solar cell module 1 with the single-sided glass module structure are not the object for improvement.

As for the solar cell module 1 with a double-sided glass module structure comprising the upper surface 20 and the lower surface 21, these solar cell modules 1 adopt double-sides solar cells for power generation, and the lower surface of the solar cell 10 is not the type of the back-contact electrode. Therefore, the back side of such solar cell 10 can absorb the incident light to increase the total photoelectric conversion efficiency of the solar cell 10. The solar cell module 1 with the double-sided glass module structure has a proper insulation performance to prevent moist and air from entering into the module to cause power degradation. Hence, the solar cell module 1 has good weather resistance and is suitable for building up power generation systems with anti-salt damages and anti-typhoon designs. Besides, the solar cell with the symmetric double-sided glass structure can provide the advantages of high mechanical strength, reduce the production of the microcracks or scratches during the construction process, and thus the solar cell with the symmetric double-sided glass structure has a proper fire resistance performance. However, as mentioned before, the lower surface of the solar cell 10 with such configuration also has the PID effect, and the PID effect on such solar cell is even more serious. Hence, it is understood that, according to one or some embodiments of the instant disclosure, the solar cell module 1 with the double-sided glass module structure is the object for improvement.

Please refer to FIG. 3. According to some embodiments, a passivation layer 102 and a protection layer structure are sequentially disposed on the lower surface 1012 of the silicon substrate 101 of the solar cell 10 in the double-sided glass module structure. According to some embodiments, the passivation layer 102 is an aluminum oxide layer, and the protection layer structure is a single-layered silicon nitride. The aluminum oxide layer is directly disposed on the lower surface 1012 of the silicon substrate 101. The silicon nitride layer is directly deposited on the surface of the aluminum oxide layer. Generally, the lower surface of the solar cell 10 has field effect passivation. The interface between the aluminum oxide layer and the silicon substrate 101 has a higher density of fixed negative charges. When the metal ions I at the lower glass 21 pass through the encapsulation material and accumulate on the lower surface of the solar cell 10, a carrier recombination center is formed to redistribute the charges of the aluminum oxide layer. As a result, the field effect passivation becomes worse, thereby reducing the power generation efficiency. This phenomenon is called the polarization-type PID (PID-polarization, or PID-p). It is understood that, the reduction of the power generation caused by the PID-p effect is more than the reduction of the power generation caused by the PID-s effect. According to the experiment results, the reduction of the power generation caused by the PID-p effect on the lower surface of the solar cell is more than four times of the reduction of the power generation caused by the PID-s effect on the upper surface of the solar cell. As compared with solar cells without any protection layer structure, the single layered silicon nitride layer on the aluminum oxide layer can provide a certain anti-PID ability.

Please refer to FIG. 3 again. According to some embodiments, a protection layer structure comprising multiple deposition layers is on the lower surface of the solar cell 10, so that the PID-p effect can be suppressed more greatly. Both the material and depositing order of the multiple deposition layers of the protection layer structure are chosen specifically. In these embodiments, the solar cell 10 comprises a silicon substrate 101, a passivation layer 102, a first protection layer 103, a second protection layer 104, a third protection layer 105, and an electrode 107. The passivation layer 102, the first protection layer 103, the second protection layer 104 and the third protection layer 105 are sequentially deposited on the lower surface 1012 of the silicon substrate 101. The electrode 107 passes through the third protection layer 105, the second protection layer 104, the first protection layer 103, and the passivation layer 102 to contact the lower surface 1012 of the silicon substrate 101. The material of the electrode 107 may be, but is not limited to, aluminum, silver or silver-aluminum composite material. For example, the electrode 107 is formed by fingers and busbars. The finger and busbar are perpendicular to each other. The fingers are made of aluminum paste, and the busbars are made of silver-aluminum paste. The electrode 107 can form a Back Surface Field (BSF) region 1013 on the lower surface 1012 of the silicon substrate 101. The BSF region 1013 reduces the surface carrier recombination rate at the interface so to increase the carrier collection rate.

According to some embodiments, the solar cell 10 is a silicon-based solar cell. The silicon substrate 101 may be, but is not limited to, a monocrystalline or polycrystalline silicon, or may be an amorphous silicon film. According to some embodiments, the material of the passivation layer 102 is aluminum oxide. The aluminum oxide makes the lower surface 1012 of the silicon substrate 101 passivated to avoid the recombination of charged carriers caused by surface impurities on the silicon substrate 101 or defects, thereby improving power generation efficiency. It is understood that, the surfaces of the solar cell 10 are not a polished and flat structure, but a relatively rough surface with concave and convex structures. Therefore, when the thickness of the passivation layer 102 is overly thin, the passivation layer 102 is prone to have an uneven thickness distribution, thus failing to perform the passivation effect of the passivation layer 102. Conversely, when the thickness of the passivation layer 102 is overly thick, the incident light from the back side of the solar cell 10 cannot be easily absorbed and utilized, and the photoelectric conversion efficiency of the solar cell 10 with the double-sided glass module structure cannot be improved efficiently. According to some embodiments, the thickness of the passivation layer 102 is less than or equal to 40 nm, and the passivation layer 102 having such thickness is sufficient to make the lower surface 1012 of the silicon substrate 101 passivated.

According to some embodiments, both the material of the first protection layer 103 and the material of the third protection layer 105 are silicon oxynitride. The material of the second protection layer 104 is silicon nitride. The chemical formula of silicon nitride is SiNx:H, which is a film material enriched with hydrogen atoms. During the high temperature sintering process of the electrode 107, the hydrogen atoms of the second protection layer 104 will diffuse into the solar cell, and passivate the metallic impurities and the silicon with unsaturated bonds in the solar cell, thereby further improving the power conversion efficiency. According to some embodiments, the thickness of the second protection layer 104 is greater than or equal to 50 nm and less than or equal to 200 nm. Both the thickness of the first protection layer 103 and the thickness of the third protection layer 105 are greater than or equal to 0.1 nm and less than or equal to 100 nm. The thickness in this range is capable of absorbing incident light with the proper wavelengths for the power generation, and also efficiently suppresses PID-p effect. Specifically, according to one or some embodiments of the instant disclosure, the thickness of the aforementioned layers is specifically designed. It is understood that, a protection layer with a non-proper thickness may have some defects. If the thickness of the protection layer is overly thin, during the sintering process of the electrode 107 at the back side of the solar cell 10, the protection layer may be easily burned through and make the aluminum oxide of the passivation layer 102 exposed, thereby destroying the field effect passivation of the aluminum oxide. Conversely, an overly thick protection layer will not only increase the production cost because of prolonged manufacture process, but also make the light to be reflected easily thus leads lesser light entering into the solar cell 10 to cause the photoelectric effect.

The main function for depositing the second protection layer 104 on the first protection layer 103 is to provide a high density of fixed positive charges to block the metal ions I from penetrating and diffusing into the passivation layer 102. The main function for depositing the third protection layer 105 on the second protection layer 104 is to form a hetero-junction to be an energy level barrier for the metal ions I upon penetrating the hetero-junction, thereby suppressing the PID-p effect. On the other hand, the refractive index of silicon oxynitride is about 1.4 to 1.6, and the refractive index of silicon nitride is about 1.6 to 3.0. Because the difference between the refractive indexes of silicon nitride and silicon oxynitride is small, the reflection rate at the interface between silicon nitride and silicon oxynitride is reduced, so that more incident light can penetrate into the protection layers and enter into the silicon substrate 101.

According to some embodiments, the material of the third protection layer 105 is silicon oxide. The silicon oxide may be, but is not limited to, silicon monoxide or silicon dioxide. The thickness of the third protection layer 105 is in a range between 0.1 nm and 100 nm. Similarly, the third protection layer 105 forms a hetero-junction with the second protection layer 104, and the hetero-junction blocks the penetration of the metal ions I. Besides, the refractive index of silicon oxide is about 1.5 to 1.6, which is less than the refractive index of silicon nitride of the second protection layer 104. Thus, in this embodiment, the solar cell has a gradually changing refractive index, and this gradually changing refractive index can reduce the reflection of the interfaces and increase the ratio of incident light.

According to some embodiments, a plurality of sets of alternately staggered structures may be disposed on the outer side of the third protection layer 105. (For example, the alternately staggered structure may be formed by alternately stacking the silicon nitride layer and the silicon oxynitride layer, or by alternately stacking the silicon nitride layer and the silicon oxide layer.) This alternately staggered structure can provide more hetero-junctions, thereby increasing the ability of blocking the metal ions I of the solar cell 10, and thus avoiding the reflection problem caused by an excessive refractive index difference.

Please refer to FIG. 3 again. According to some embodiments, an anti-reflective layer 109 and a heterogeneous doping layer 108 are further formed on the upper surface of the solar cell 10. Specifically, in this embodiment, the heterogeneous doping layer 108 is on the upper surface of the silicon substrate 101 and the heterogeneous doping layer 108 comprises a second doping material. The anti-reflective layer 109 is on a surface of the heterogeneous doping layer 108 opposite to the silicon substrate 101. According to some embodiments, the material of the anti-reflective layer 109 may be selected from the group consisting of aluminum oxide, silicon nitride, silicon oxide, silicon oxynitride, and the composite thereof. According to some embodiments, the thickness of the anti-reflective layer 109 is in a range between 50 nm and 200 nm. In addition to providing a passivation ability, the anti-reflective layer 109 within the thickness range can efficiently absorb the incident light. Therefore, according to one or some embodiments of the instant disclosure, for the solar cell comprising the anti-reflective layer 109 within this thickness range, the light is not reflected easily caused by an overly thick anti-reflective layer 109. The manufacturing process and the production cost for the solar cell are not overly increased due to an overly thick anti-reflective layer 109. According to some embodiments, the upper surface of the solar cell 10 comprises an electrode 110. The electrode 110 passes through the anti-reflective layer 109 and contacts the silicon substrate 101. Therefore, the electrode 110 on the upper surface 1011 of the silicon substrate 101 and the electrode 107 on the lower surface 1012 together form an electronic field, so that the carrier movement are guided by the electronic field. The material of the electrode 110 may be, but is not limited to, aluminum, silver, or silver-aluminum composite material.

Specifically, the solar cell 10 in one or some embodiments of the instant disclosure can be manufactured by current industrial solar cell manufacture equipment. Moreover, according to one or some embodiments, plasma enhanced chemical vapor deposition (PECVD) process can be applied to form the passivation layer 102, the protection layers and the anti-reflective layer 109. After the deposition layers are formed, holes can be ablated on the passivation layer 102 and the protection layers or anti-reflective layer 109 by lasers. Metals, such as aluminum, silver, or silver-aluminum composite material, are filled in the holes by screen printing or deposition process, and formed on predetermined positions of the upper surface and the lower surface of the solar cell 10. Therefore, after the sintering process, the electrode 110 and the electrode 107 can be formed respectively.

While the instant disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A solar cell comprising:
a silicon substrate comprising a first doping material, wherein the silicon substrate has a lower surface;
an aluminum oxide layer on the lower surface of the silicon substrate;
a first silicon oxynitride layer on a surface of the aluminum oxide layer opposite to the silicon substrate;
a silicon nitride layer on a surface of the first silicon oxynitride layer opposite to the aluminum oxide layer; and
a second silicon oxynitride layer on a surface of the silicon nitride layer opposite to the first silicon oxynitride layer.

2. The solar cell according to claim 1, further comprising an electrode passing through the second silicon oxynitride layer, the silicon nitride layer, the first silicon oxynitride layer, and the aluminum oxide layer to contact the silicon substrate.

3. The solar cell according to claim 2, further comprising a heterogeneous doping layer and an anti-reflective layer, wherein the silicon substrate further comprising an upper surface, the heterogeneous doping layer is on the upper surface of the silicon substrate and comprises a second doping material, and the anti-reflective layer is on a surface of the heterogeneous doping layer opposite to the silicon substrate.

4. The solar cell according to claim 3, wherein a material of the anti-reflective layer comprises at least one selected from the group consisting of aluminum oxide, silicon nitride, silicon oxide, and silicon oxynitride.

5. The solar cell according to claim 1, wherein a thickness of the first silicon oxynitride layer is in a range between 0.1 nm and 100 nm, a thickness of the silicon nitride layer is in a range between 50 nm and 200 nm, and a thickness of the second silicon oxynitride layer is in a range between 0.1 nm and 100 nm.

6. The solar cell according to claim 1, wherein a thickness of the aluminum oxide layer is less than 40 nm.

7. A solar cell comprising:
a silicon substrate comprising a first doping material, wherein the silicon substrate has a lower surface;
an aluminum oxide layer on the lower surface of the silicon substrate;
a silicon oxynitride layer on a surface of the aluminum oxide layer opposite to the silicon substrate;
a silicon nitride layer on a surface of the silicon oxynitride layer opposite to the aluminum oxide layer; and
a silicon oxide layer on a surface of the silicon nitride layer opposite to the silicon oxynitride layer.

8. The solar cell according to claim 7, further comprising an electrode passing through the silicon oxide layer, the silicon nitride layer, the silicon oxynitride layer, and the aluminum oxide layer to contact the lower surface of the silicon substrate.

9. The solar cell according to claim 8, further comprising a heterogeneous doping layer and an anti-reflective layer, wherein the silicon substrate further comprises an upper surface, the heterogeneous doping layer is on the upper surface of the silicon substrate and comprises a second doping material, and the anti-reflective layer is on a surface of the heterogeneous doping layer opposite to the silicon substrate.

10. The solar cell according to claim 7, wherein a thickness of the silicon oxynitride layer is in a range between 0.1 nm and 100 nm, a thickness of the silicon nitride layer is in a range between 50 nm and 200 nm, and a thickness of the silicon oxide layer is in a range between 0.1 nm and 100 nm.

11. The solar cell according to claim 7, wherein a thickness of the aluminum oxide layer is less than 40 nm.
